(19) United States
(12) Patent Application Publication
(10) Pub. No.: US 2011/0285016 A1
(43) Pub. Date: Nov. 24, 2011

(54) SEMICONDUCTOR DEVICE AND METHOD OF MANUFACTURING THE SAME

(75) Inventor: Takeshi MATSUMOTO, Hyogo (JP)

(73) Assignee: PANASONIC CORPORATION, Osaka (JP)

(21) Appl. No.: 13/111,034

(22) Filed: May 19, 2011

(30) Foreign Application Priority Data
May 20, 2010 (JP) 2010-116759

(51) Int. Cl. H01L 23/498; H01L 21/50

(52) U.S. Cl. 257/737; 438/108; 438/118; 257/E23.068; 257/E21.499

(57) ABSTRACT

A semiconductor device includes a substrate and a stress generating film. A first surface of the substrate includes a protruding part at each of two end portions. The substrate includes a semiconductor element. The stress generating film is formed so as to come into contact with a second surface of the substrate that is opposite to the first surface of the substrate. The stress generating film is in a shape which causes a second stress that offsets at least a part of a first stress occurring as a result of bonding between an external substrate and the protruding part.

### BACKGROUND OF THE INVENTION

(1) Field of the Invention

The present invention relates to a semiconductor device which is bonded to an external substrate, and to a method of manufacturing the semiconductor device.

(2) Description of the Related Art

In recent years, flip-chip bonding using bumps is on its way of becoming the mainstream of technology for bonding semiconductor chips.

Japanese Unexamined Patent Application Publication No. 2003-229451 (referred to as the conventional technology A hereafter) discloses a technology of using two-stage bumps to reduce damage which is caused to a semiconductor device as a result of flip-chip bonding.

### SUMMARY OF THE INVENTION

However, the conventional technology A has the following problem.

FIG. 5 is a diagram explaining the problem of the conventional technology A.

Here, (a) in FIG. 5 shows a configuration of a semiconductor device 1000 which employs the conventional technology A. It should be noted that (a) in FIG. 5 shows a two-stage bump as a bump 532 in a simplified shape.

As shown in (a) of FIG. 5, an active area 512 is formed in a substrate 511. The active area 512 includes an electronic circuit. In the active area 512, multiple semiconductor elements, such as transistors, are formed. Each of the semiconductor elements is, for example, a metal oxide semiconductor field effect transistor (MOSFET).

An electrode pad 531 is formed on the substrate 511 at each of two end portions. Each of the semiconductor elements formed in the active area 512 is electrically connected to the electrode pad 531 via a wire which is not illustrated.

A protective film 520 is formed on an upper surface of the substrate 511, except for parts where the electrode pads 531 are formed. In other words, before the bumps 532 are formed, the electrode pads 531 are exposed to the outside. The bump 532 is formed on each of the electrode pads 531. The electrode pad 531 and the bump 532 are electrically connected.

Here, (b) in FIG. 5 shows that the semiconductor device 1000 and an external substrate 1200 are bonded.

In (b) of FIG. 5, the external substrate 1200 is a wiring board, for example. An external electrode 1210 is formed on the external substrate 1200 at a position where the external substrate 1200 is electrically connected to the semiconductor device 1000. Here, the external electrode 1210 and the bump 532 are electrically connected by a bonding pressure applied between the external electrode 1210 and the bumps 532. With this, the external substrate 1200 and the semiconductor device 1000 are bonded.

It should be noted that a space between the protective film 520 of the semiconductor device 1000 and a lower surface of the external substrate 1200 except for parts where the external electrodes 1210 are formed is filled with a bonding resin 550. The bonding resin 550 is mainly made of an underfill agent, for example.

Here, (c) in FIG. 5 shows a stress which occurs to the bonding resin 550 as a result of the bonding between the semiconductor device 1000 and the external substrate 1200.

In the present case, a stress P30 occurs to the bonding resin 550 in the direction toward the external substrate 1200.

The stress P30 includes an edge stress P31 and a center stress P32. The edge stress P31 occurs near the bump 532. More specifically, the edge stress P31 occurs to the substrate 511 at the position near the bump 532. The center stress P32 occurs to the substrate 511 at a center position between the two bumps 532.

The edge stress P31 is substantially larger than the center stress P32. For this reason, among the semiconductor elements formed in the active area 512, the semiconductor elements formed near the position which is under the edge stress P31 suffer from a larger stress than the semiconductor elements formed near the position which under the center stress P32.

That is to say, the stress resulting from the bonding between the semiconductor device 1000 and the external substrate 1200 varies depending on a position on the substrate 511. More specifically, a different stress occurs for each of the semiconductor elements formed in the active area 512 of the substrate 511.

On account of this, some of the semiconductor elements formed in the substrate 511 are more likely to cause a defect. As an example of the defect, when the substrate 511 is damaged, leading to damage to some of the semiconductor elements, electrical characteristics of the semiconductor elements substantially differ from designed values.

The present invention is conceived in view of the aforementioned problem, and has an object to provide a semiconductor device and a method of manufacturing the same, which are capable of preventing a defect caused, as a result of bonding to an external substrate, to an element formed in a substrate.

In order to achieve the aforementioned object, the semiconductor device according to an aspect of the present invention is bonded to an external device. The semiconductor device includes: a substrate which is flat; and a stress generating film which is formed on at least a part of the substrate, wherein the substrate includes a first surface and a second surface which is opposite to the first surface, the first surface of the substrate includes a protruding part at each of two end portions, the substrate includes a semiconductor element, the stress generating film is formed so as to come into contact with the second surface of the substrate, and the stress generating film is in a shape which causes a second stress that offsets at least a part of a first stress occurring as a result of bonding between the external substrate and the protruding part.

The semiconductor device includes the substrate and the stress generating film. The first surface of the substrate includes a protruding part at each of two end portions. The substrate includes a semiconductor element. The stress generating film is formed so as to come into contact with the second surface of the substrate. The stress generating film is in a shape which causes a second stress that offsets at least a part of a first stress occurring as a result of bonding between the external substrate and the protruding part.

With this, the stress occurring to the substrate as a result of the bonding between the semiconductor device and the external substrate can be reduced, as compared to the case where the stress generating film is not formed on the substrate. Accordingly, a defect caused, as a result of the bonding between the semiconductor device and the external substrate, to the semiconductor element formed in the substrate can be prevented.

Also, preferably, the protruding part includes: an electrode pad which is electrically connected to the semiconductor element; and a bump which is electrically connected to the electrode pad.

Moreover, preferably, the stress generating film is in a shape of a closed loop; and the stress generating film is formed along a periphery of the second surface of the substrate.

Furthermore, preferably, the stress generating film is in a shape of a closed loop; and the stress generating film is in a shape of an octagon.

Also, preferably, the stress generating film is in a shape of an ellipse.

Moreover, preferably, the stress generating film includes a plurality of closed-loop-shaped flat sub-films which are different in size.

Furthermore, preferably, a side surface of the substrate is flush with a side surface of the stress generating film.

Also, preferably, the stress generating film is made of a resin material, in whole or in part.

Moreover, preferably, the stress generating film is made of an oxide film or a nitride film, in whole or in part.

Furthermore, preferably, the semiconductor device is bonded to the external substrate according to a flip-chip method.

The method of manufacturing the semiconductor device according to another aspect of the present invention is a method of manufacturing a semiconductor device which includes a flat substrate having a semiconductor element and which is bonded to an external substrate. The flat substrate includes a first surface and a second surface which is opposite to the first surface. The method includes: forming a protruding part on the first surface of the flat substrate at each of two end portions; forming a stress generating film so that the stress generating film comes into contact with the second surface of the flat substrate; and forming the stress generating film in a shape which causes a second stress that offsets at least a part of a first stress occurring as a result of bonding between the external substrate and the protruding part.

Also, preferably, the method of manufacturing the semiconductor device further includes grinding the flat substrate to reduce a thickness of the flat substrate to 50 μm to 300 μm, the grinding being performed between the forming of a protruding part and the forming of a stress generating film.

Moreover, preferably, the semiconductor device is bonded to the external substrate according to a flip-chip method.

The present invention can prevent a defect caused, as a result of bonding between a semiconductor device and an external substrate, to a semiconductor element formed in a substrate.

### FURTHER INFORMATION ABOUT TECHNICAL BACKGROUND TO THIS APPLICATION

The disclosure of Japanese Patent Application No. 2010-116759 filed on May 20, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a diagram explaining a semiconductor device in an embodiment;

FIG. 2 is a diagram explaining a shape of a stress generating film;

FIG. 3 is a diagram explaining a method of manufacturing the semiconductor device;

FIG. 4 is a diagram explaining the method of manufacturing the semiconductor device; and

FIG. 5 is a diagram explaining a problem of the conventional technology A.

### DESCRIPTION OF THE PREFERRED EMBODIMENT

The following is a description of an embodiment according to the present invention, with reference to the drawings. It should be noted that identical components in the drawings are assigned the same numeral and, therefore, the detailed explanation thereof may not be repeated. Also note that the drawings are illustrated by deformation for the purpose of, for example, emphasizing a part of components shown, and that a ratio between the sizes of the components in the drawings may be different from the actual ratio.

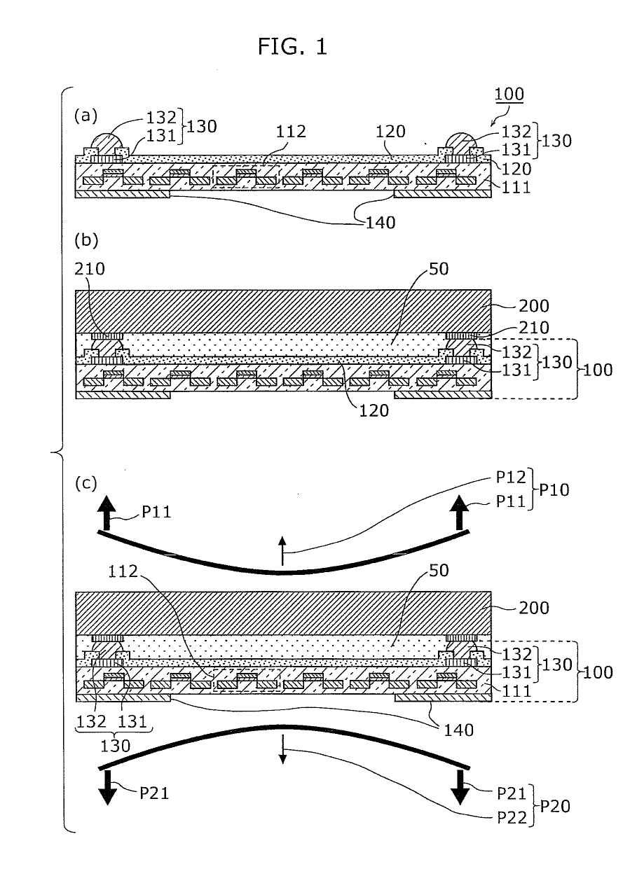

FIG. 1 is a diagram explaining a semiconductor device 100 in the embodiment.

Here, (a) in FIG. 1 shows a cross-sectional view of the semiconductor device 100 in the present embodiment.

As shown in (a) of FIG. 1, the semiconductor device 100 includes a substrate 111, a protective film 120, an electrode pad 131, a bump 132, and a stress generating film 140.

The substrate 111 is flat, and is mainly made of, for example, silicon (Si) and gallium arsenide (GaAs). The thickness of the substrate 111 is 50 μm to 300 μm, for example.

The substrate 111 has a first surface and a second surface which are opposite to each other. On the first surface, the electrode pad 131, for example, is formed. On the second surface, the stress generating film 140 is formed. In (a) of FIG. 1, the first surface is an upper surface whereas the second surface is a lower surface (namely, a bottom surface).

Note that, when the semiconductor device 100 is flipped over, the first surface is the lower surface and the second surface is the upper surface.

In the substrate 111, a plurality of semiconductor elements 112 are arranged horizontally. Here, the semiconductor elements 112 may be formed on the substrate 111. In short, the substrate 111 includes the semiconductor elements 112.

It should be noted that the number of the semiconductor elements included in the substrate 111 may be one.

The semiconductor element 112 is a MOSFET, for example. Here, the semiconductor element 112 is not limited to the MOSFET, and may be a different kind of semiconductor element.

An electrode pad 131 is formed on the first surface of the substrate 111 at each of two end portions. The electrode pad 131 is formed for electrically connecting the semiconductor elements 112 and an external substrate 200. The electrode pad 131 is made of aluminum (Al), for example.

Each of the semiconductor elements 112 is electrically connected to the electrode pad 131 via a wire which is not illustrated.

A protective film 120 is formed as a surface protective film on the first surface of the substrate 111, except for parts where the electrode pads 131 are formed. Also, the protective film 120 is formed on a part of the electrode pad 131. The protective film 120 is mainly made of silicon nitride (SiN), for example.

Note that the protective film 120 does not need to be formed on the aforementioned part of the electrode pad 131.

In other words, before the bumps 132 are formed, at least a part of each of the electrode pads 131 is exposed to the outside.

After the protective film 120 is formed, the bump 132 is formed on each of the electrode pads 131. The electrode pad 131 and the bump 132 are electrically connected.

The bump 132 is formed to establish electrical connection with the external substrate which is a package substrate or the like. The bump 132 is mainly made of gold (Au) and copper (Cu), for example. In general, the bump 132 is formed according to a plating method.

The electrode pad 131 and the bump 132 combine to make a protruding part 130. To be more specific, the protruding part 130 includes: the electrode pad 131 electrically connected to the semiconductor elements 112; and the bump 132 electrically connected to the electrode pad 131.

That is, the protruding part 130 including the electrode pad 131 and the bump 132 is formed on the first surface of the substrate 111 at each of the two end portions.

As one of the characteristics in the present embodiment, the stress generating film 140 is formed so as to come into contact with the second surface of the substrate 111. Note that the stress generating film 140 is formed in such a manner that a side surface of the stress generating film 140 is flush with a side surface of the substrate 111. That is, the side surface of the substrate 111 and that of the stress generating film 140 are flush with each other.

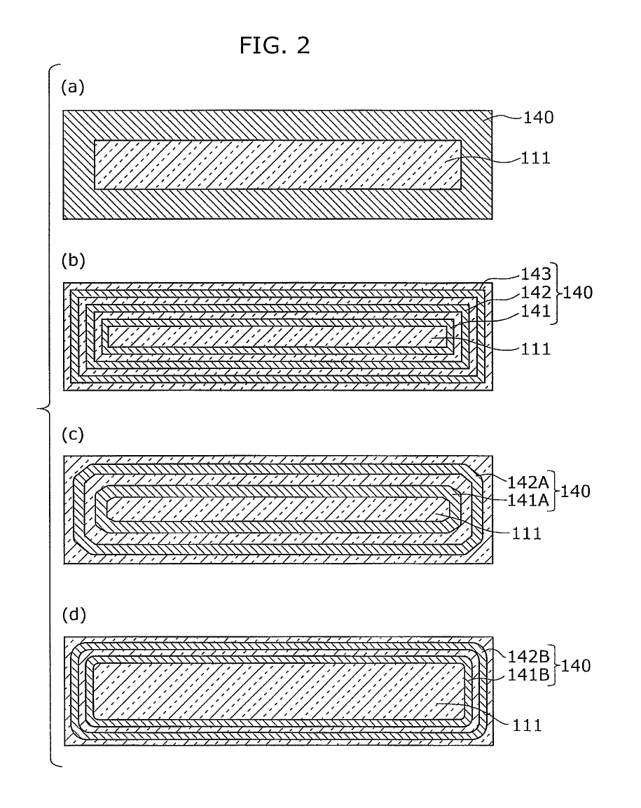

FIG. 2 is a diagram explaining the shape of the stress generating film 140. FIG. 2 shows the shape of the stress generating film 140 when viewed from the second surface (namely, the bottom surface) of the substrate 111.

Here, (a) in FIG. 2 is a top view showing an example of the shape of the stress generating film 140. In (a) of FIG. 2, the substrate 111 which is not included in the stress generating film 140 is illustrated for the purpose of explanation. Also in (b), (c), and (d) of FIG. 2 described later, the substrate 111 is illustrated for the purpose of explanation.

As shown in (a) of FIG. 2, the stress generating film 140 is in the shape of a closed loop. Moreover, as shown, the stress generating film 140 is formed along a periphery of the second surface of the substrate 111.

The stress generating film 140 is mainly made of a resin material. To be more specific, the stress generating film 140 is made of the resin material, in whole or in part. This resin material is polyimide, for example. When a resin material is used for forming the stress generating film 140, a resin coating method is employed.

Note that the main material used for forming the stress generating film 140 is not limited to a resin. The stress generating film 140 may be mainly made of an oxide film or a nitride film (i.e., a SiN film). That is, the stress generating film 140 may be made of the oxide film or the nitride film, in whole or in part. In this case, the stress generating film 140 is formed by a chemical vapor deposition (CVD) process.

The stress generating film 140 formed in the semiconductor device 100 generates a stress in the direction from the inside of the semiconductor device 100 toward the second surface (namely, the bottom surface) of the substrate 111.

The semiconductor device 100 and the external substrate 200 shown in (b) of FIG. 1 are electrically connected. Here, the semiconductor device 100 and the external substrate 200 are bonded according to a flip-chip method.

An external electrode 210 is formed on the external substrate 200 at a part where the external substrate 200 and the semiconductor device 100 are electrically connected. Here, the external electrode 210 and the bump 132 are electrically connected by a bonding pressure applied between the external electrode 210 and the bumps 132.

More specifically, the protruding part 130 of the semiconductor device 100 and the external electrode 210 of the external substrate 200 are electrically connected.

It should be noted that the external electrode 210 may be formed in the external substrate 200 in such a manner that a lower surface of the external electrode 210 is exposed to the outside. In this case, the external substrate 200 includes the external electrode 210. Also, this case means that the protruding part 130 of the semiconductor device 100 and the external substrate 200 (that is, the external electrode 210) are electrically connected. When the protruding part 130 of the semiconductor device 100 and the external substrate 200 (that is, the external electrode 210) are electrically connected, this means that the semiconductor device 100 and the external substrate 200 are bonded.

The external substrate 200 is a package substrate, for example. It should be noted that a space between the protective film 120 of the semiconductor device 100 and a lower surface of the external substrate 200 except for parts where the external electrodes 210 are formed is filled with a bonding resin 50. The bonding resin 50 is mainly made of an underfill agent, for example.

Here, (c) in FIG. 1 shows stresses occurring as a result of the bonding between the semiconductor device 100 and the external substrate 200.

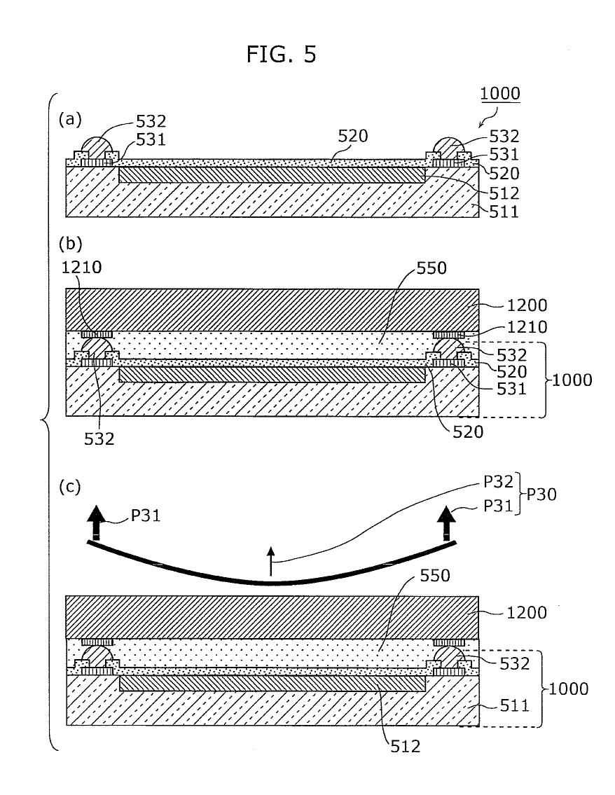

As in the case of the bonding resin 550 shown in (c) of FIG. 5 above, a stress P10 occurs to the bonding resin 50 in the direction toward the external substrate 200. The stress P10 is similar in force to the stress P30 described above. That is, the stress P10 occurs to the bonding resin 50 as a result of the bonding between the semiconductor 100 and the external substrate 200.

The stress P10 is a first stress occurring as a result of the bonding between the external substrate 200 (i.e., the external electrode 210) and the protruding part 130 (i.e., the semiconductor device 100).

The stress P10 includes an edge stress P11 and a center stress

P12. The edge stress P11 occurs near the protruding part 130 (i.e., the bump 132). More specifically, the edge stress P11 occurs to the substrate 111 at the position near the protruding part 130 (i.e., the bump 132). The center stress P12 occurs to the substrate 111 at a center position between the two protruding parts 130 (i.e., the two bumps 132). Here, the edge stress P11 is substantially larger than the center stress P12.

A stress P20 occurs to the stress generating film 140 which is formed on the second surface (i.e., the bottom surface) of the substrate 111.

The stress P20 is opposite in direction to the stress P10. To be more specific, the stress P20 occurs in the direction from the bonding resin 50 to the second surface of the substrate 111. The stress P20 offsets almost the whole of the stress P10. However, the stress P20 may offset a part of the stress P10.

The stress generating film 140 is in a shape which causes the stress P20 (may also be referred to as the second stress) that offsets almost the whole of the stress P10, i.e., the first stress. Here, the stress generating film 140 may be in a shape which causes, as a result of the bonding between the external substrate 200 (i.e., the external electrode 210) and the protruding part 130, the stress P20 (i.e., the second stress) that offsets a part of the stress P10 (i.e., the first stress).

The stress P20 includes an edge stress P21 and a center stress P22. The edge stress P21 occurs near the protruding part 130 (i.e., the bump 132). More specifically, the edge stress P21 occurs to the substrate 111 at the position near the protruding part 130 (i.e., the bump 132). The center stress P22 occurs to the substrate 111 at a center position between the two protruding parts 130 (i.e., the two bumps 132). Here, the edge stress P21 is substantially larger than the center stress P22.

Moreover, the direction of the edge stress P21 is opposite to that of the edge stress P11. The direction of the center stress P22 is opposite to that of the center stress P12. The edge stress P21 is approximately the same in force as the edge stress P11. Also, the center stress P22 is approximately the same in force as the center stress P12. In other words, the stress P20 offsets almost the whole of the stress P10.

In the case of the conventional semiconductor device 1000 described above, only the stress P30 which similar in force to the stress P10 occurs as a result of the bonding between the semiconductor device 1000 and the external substrate 1200. For this reason, different stresses are caused depending on different positions on the substrate 511, as a result of the bonding between the semiconductor device 1000 and the external substrate 1200. To be more specific, a different stress occurs for each of the semiconductor elements formed on the active area 512 of the substrate 511.

On account of this, some of the semiconductor elements formed in the substrate 511 are more likely to cause a defect. As an example of the defect, when the substrate 511 is damaged, leading to damage to some of the semiconductor elements, electrical characteristics of the semiconductor elements substantially differ from designed values.

As another example of the defect, among the semiconductor elements formed in the active area 512, the semiconductor elements near the end portions of the substrate 511 have electrical characteristics substantially different from electrical characteristics of the semiconductor elements near the center of the substrate 511.

On the other hand, in the case of the semiconductor device 100 in the present embodiment, the stress generating film 140 is formed on the second surface (i.e., the bottom surface) of the substrate 111. The stress P20 offsets almost the whole of the stress P10.

The semiconductor device 100 including this stress generating film 140 can cause the edge stress P21 in the direction opposite to the direction of the edge stress P11. Moreover, the center stress P22 can be caused in the direction opposite to the direction of the center stress P12.

Accordingly, almost the whole of the stress P10 is offset by the stress P20.

Therefore, almost no stress occurs to the substrate 111 even with the bonding between the semiconductor device 100 and the external substrate 200. More specifically, a stress adversely affecting the substrate 111 as a result of the bonding between the semiconductor device 100 and the external substrate 200 can be prevented from occurring. This can prevent a defect, such as damage to the substrate 111, caused as a result of the bonding between the semiconductor device 100 and the external substrate 200.

That is to say, even when the semiconductor device 100 and the external substrate 200 are bonded, almost no stress occurs to the semiconductor elements 112 formed in the substrate 111. More specifically, a stress adversely affecting the semiconductor elements 112 formed in the substrate 111 as a result of the bonding between the semiconductor device 100 and the external substrate 200 can be prevented from occurring.

This can prevent the defect that, among the semiconductor elements 112 formed in the substrate 111, the semiconductor elements near the end portions of the substrate 111 have electrical characteristics substantially different from electrical characteristics of the semiconductor elements 112 near the center of the substrate 111.

That is, the defect caused as a result of the bonding between the semiconductor device 100 and the external substrate 200 is prevented from occurring to the semiconductor elements 112 formed in the substrate 111.

Conventionally, semiconductor elements cannot have been arranged under electrode pads because this may increase differences in electrical characteristics of the semiconductor elements formed in a substrate of a semiconductor device. However, since the defect can be prevented in the present embodiment as described above, flexibility in arranging the semiconductor elements can be increased. Moreover, this leads to an increase in packing density of a semiconductor chip, i.e., a semiconductor device, thereby allowing reduction of costs.

When the stress generating film 140 is in the shape as shown in (a) of FIG. 2, the edge stress P21 strongly opposes the edge stress P11.

Note that the shape of the stress generating film 140 is not limited to the one shown in (a) of FIG. 2. The stress generating film 140 may be in any shape as long as the stress P20 offsetting almost the whole of the stress P10 is caused as a result of the bonding between the external substrate 200 (i.e., the external electrode 210) and the protruding part 130.

For example, the stress generating film 140 may be in any of the shapes as shown in (b), (c), and (d) of FIG. 2.

The stress generating film 140 shown in (b) of FIG. 2 includes flat sub-films 141, 142, and 143 which are different in size. Each of the flat sub-films 141, 142, and 143 is in the shape of a closed loop. More specifically, the stress generating film 140 includes a plurality of closed-loop-shaped flat sub-films in different sizes. This structure allows the edge stress P21 to act more strongly.

Note that the number of flat sub-films included in the stress generating film 140 is not limited to three. The stress generating film 140 may include two flat sub-films, or may include four or more flat sub-films.

The stress generating film 140 shown in (c) of FIG. 2 includes flat sub-films 141A and 142A which are different in size. Each of the flat sub-films 141A and 142A is in the shape of a closed loop, and also is in the shape of an octagon. That is, the stress generating film 140 is in the shape of an octagon.

Edge parts of each of the flat sub-films 141A and 142A are cut, for example. Here, the edge parts correspond to corner parts of the substrate 111.

With this structure, the edge stress P21 can be prevented from concentrating on the end portions of the substrate 111 of the semiconductor device 100. This means that the edge stress P21 is prevented from occurring heavily only to the end portions of the substrate 111.

Note that the number of flat sub-films included in this stress generating film 140 is not limited to two. The stress generating film 140 may include three or more flat sub-films.

The stress generating film 140 shown in (d) of FIG. 2 includes flat sub-films 141B and 142B which are different in size. Each of the flat sub-films 141B and 142B is in the shape of a closed loop, and also is in the shape of an ellipse. That is, the stress generating film 140 is in the shape of an ellipse.

Edge parts of each of the flat sub-films 141B and 142B, which correspond to the corner parts of the substrate 111, are made round, for example. With this structure, the edge stress P21 can be prevented from concentrating on the end portions of the substrate 111 of the semiconductor device 100. This means that the edge stress P21 is prevented from occurring heavily only to the end portions of the substrate 111.

Note that the shape of the stress generating film 140 is not limited to the closed-loop shape as long as the stress generating film 140 is formed along the periphery of the second surface of the substrate 111. That is to say, the stress generating film 140 may be in the shape of an open loop along which a stress generating film is formed intermittently. For example, the stress generating film 140 may be formed in a discontinuous shape, that is, the stress generating film 140 may have clearances in between.

### (Method of Manufacturing the Semiconductor Device)

Next, the method of manufacturing the semiconductor device 100 is described.

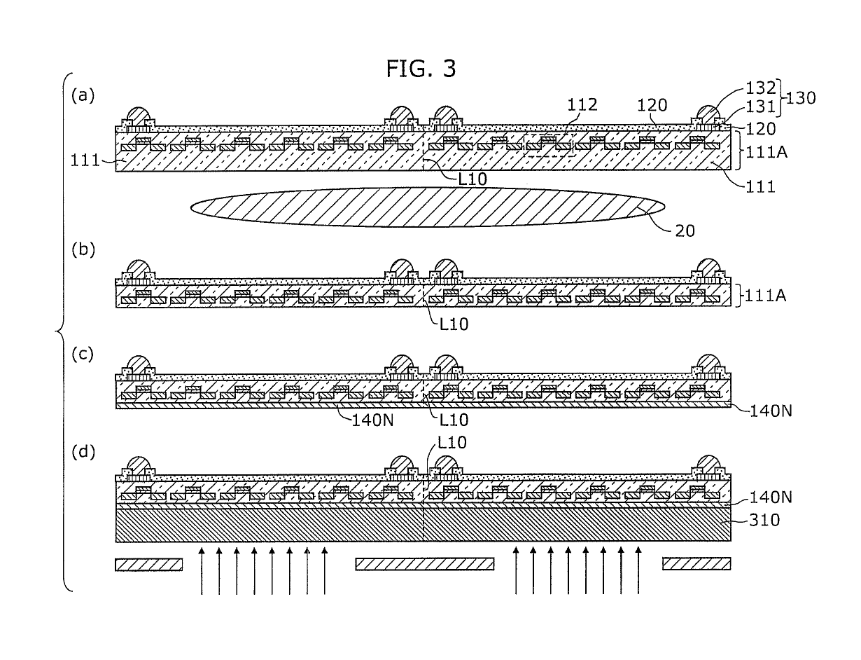

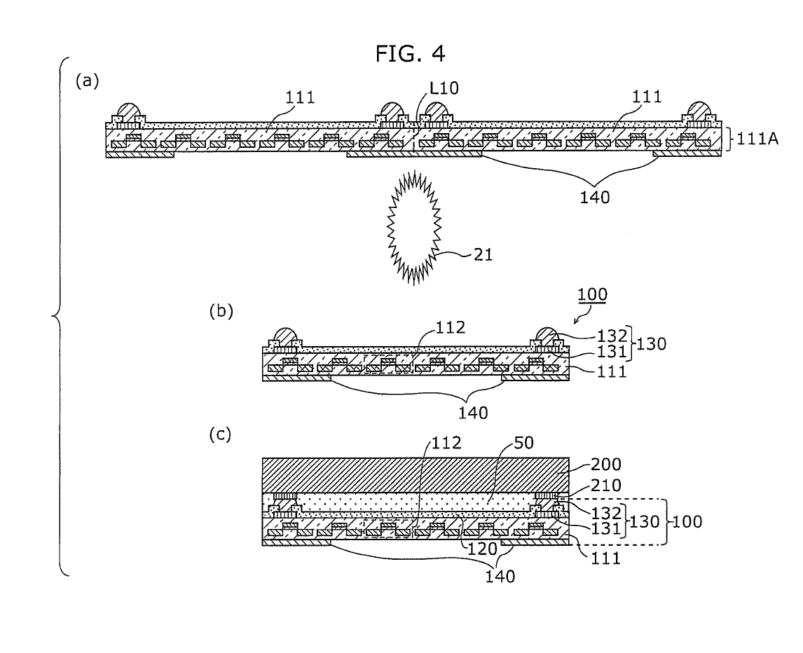

FIGS. 3 and 4 are diagrams explaining the method of manufacturing the semiconductor device 100.

It should be noted that each process described below can be executed according to a well-known process technology. Thus, detailed explanations regarding process conditions and the like are omitted where deemed appropriate. Also note that materials and processes used in the following description are only typical examples, and are not intended to limit the semiconductor device 100 and the method of manufacturing the same according to the present invention. The present invention includes other embodiments implemented using different materials and processes whose suitabilities are known.

As shown in (a) of FIG. 3, a semiconductor wafer 111A which is a substrate is divided into a plurality of substrates 111 by a boundary line L10.

Firstly, the plurality of semiconductor elements 112 are formed in each of the substrates 111. The substrate 111 is mainly made of, for example, Si and GaAs. The semiconductor element 112 is a MOSFET, for example.

Next, a process of forming the protruding part is executed. By this protruding-portion forming process, the electrode pad 131 is formed on the first surface of the substrate 111 at each of the two end portions. Each of the semiconductor elements 112 is electrically connected to the electrode pad 131 via a wire which is not illustrated. The electrode pad 131 is made of Al, for example.

Following this, the protective film 120 is formed on the first surface of the substrate 111, except for the parts where the electrode pads 131 are formed, so that the upper surfaces of the electrode pads 131 are exposed to the outside. The protective film 120 is mainly made of SiN, for example.

Then, the bump 132 is formed on the electrode pad 131. The bump 132 is mainly made of Au and Cu, for example. In general, the bump 132 is formed according to a plating method. In this way, the protruding part 130 including the electrode pad 131 and the bump 132 is formed.

More specifically, by the protruding-portion forming process, the protruding part 130 is formed on the first surface of the substrate 111 at each of the two end portions.

Next, a back grinding process is executed. By the back grinding process, a lower surface of the semiconductor wafer 111A is ground by, for example, a flat grindstone 20 of a back grinding device which is not shown, until the thickness of the semiconductor wafer 111A is reduced to approximately 50 μm to 300 μm. To be more specific, by the back grinding process, the lower surface of the substrate 111 is ground until the thickness of the substrate 111 is reduced approximately 50 μm to 300 μm. As a result, the thickness of the semiconductor wafer 111A is reduced approximately to 50 μm to 300 μm, as shown in (b) of FIG. 3.

It should be noted that, in the case where the semiconductor elements are formed in the semiconductor wafer 111A, the semiconductor wafer 111A is made thick to some extent to prevent damage. However, in the present embodiment, the process of grinding the semiconductor wafer 111A is performed.

By this back grinding process, the substrate 111 is ground so that the thickness is reduced to 50 μm to 300 μm.

Here, depending on the material used for forming the stress generating film 140 in the following process, the film thickness of the semiconductor wafer 111A does not need to be reduced. In such a case, the back grinding process may not be performed.

Next, a process of forming the stress generating film is executed. By this stress-generating-film forming process, a stress generating film 140N is formed on the bottom surface of the semiconductor wafer 111A serving as the substrate as shown in (c) of FIG. 3. More specifically, the stress generating film 140N is formed, coming into contact with the second surface (i.e., the bottom surface) of the substrate 111.

To be more specific, by the stress-generating-film forming process, the stress generating film 140N is formed so as to come into contact with the second surface of the substrate 111.

The stress generating film 140N is mainly made of a resin material. This resin material is polyimide, for example. When a resin material is used for forming the stress generating film 140N, a resin coating method is employed.

Note that the main material used for forming the stress generating film 140N is not limited to a resin. The stress generating film 140N may be mainly made of an oxide film or a nitride film (i.e., a SiN film). In this case, the stress generating film 140N is formed by a CVD process.

Next, a patterning process is executed. By the patterning process, a coating of a photoresist 310 is applied to a lower surface of the stress generating film 140N. After this, pattern exposure and development are executed. In this way, the patterning process is performed on each of the stress generating films 140N. As a result, the shape of the stress generating film 140N is changed into the shape of the aforementioned stress generating film 140.

To be more specific, by the patterning process, the stress generating film 140N is changed into the aforementioned stress generating film 140 as shown (a) of FIG. 4. As described above, the stress generating film 140 is in the shape which causes the stress P20 (i.e., the second stress) that offsets almost the whole of the stress P10 (i.e., the first stress).

That is to say, by the patterning process, the stress generating film 140N is formed into a shape which causes the second stress that offsets at least a part of the first stress occurring as a result of the bonding between the external substrate 200 and the protruding part 130.

Next, a heat treatment is performed on the semiconductor wafer 111A as necessary. Note that the heat treatment does not need to be performed.

Following this, a dicing process is performed. By the dicing process, the semiconductor wafer 111A is cut along the boundary line L10 by a dicing blade 21. As a result, a plurality of semiconductor devices 100 shown in (b) of FIG. 4 are formed. As shown in (a) of FIG. 4, the stress generating film 140 is formed on the lower surface of the semiconductor wafer 111A and includes the boundary line L10.

In this case, the semiconductor wafer 111A and the stress generating film 140 are cut simultaneously along the boundary line L10. Accordingly, the side surface of the substrate 111 is flush with that of the stress generating film 140.

Next, as shown in (c) of FIG. 4, the semiconductor device 100 is electrically connected to the external substrate 200. Here, the semiconductor device 100 and the external substrate 200 are bonded according to the flip-chip method. The external electrode 210 is formed on the external substrate 200 at the part where the external substrate 200 and the semiconductor device 100 are electrically connected. Here, the external electrode 210 and the bump 132 are electrically connected by the bonding pressure applied between the external electrode 210 and the bumps 132.

It should be noted that the space between the protective film 120 of the semiconductor device 100 and the lower surface of the external substrate 200 except for the parts where the external electrodes 210 are formed is filled with the bonding resin 50.

The semiconductor device 100 manufactured according to this method includes the stress generating film 140 formed on the second surface (i.e., the bottom surface) of the substrate 111. Thus, as explained above, the stress P20 can be generated in the direction opposite to the direction of the stress P10. Here, the stress P20 offsets almost the whole of the stress P10, as described above.

Therefore, almost no stress occurs to the substrate 111 even with the bonding between the semiconductor device 100 and the external substrate 200. More specifically, a stress adversely affecting the substrate 111 as a result of the bonding between the semiconductor device 100 and the external substrate 200 can be prevented from occurring. This can prevent a defect, such as damage to the substrate 111, caused as a result of the bonding between the semiconductor device 100 and the external substrate 200.

That is to say, even when the semiconductor device 100 and the external substrate 200 are bonded, almost no stress occurs to the semiconductor elements 112 formed in the substrate 111. More specifically, a stress adversely affecting the semiconductor elements 112 formed in the substrate 111 as a result of the bonding between the semiconductor device 100 and the external substrate 200 can be prevented from occurring.

This can prevent the defect that, among the semiconductor elements 112 formed in the substrate 111, the semiconductor elements near the end portions of the substrate 111 have electrical characteristics substantially different from electrical characteristics of the semiconductor elements 112 near the center of the substrate 111.

That is, the defect caused as a result of the bonding between the semiconductor device 100 and the external substrate 200 is prevented from occurring to the semiconductor elements 112 formed in the substrate 111.

The semiconductor device 100 according to the present invention has been explained thus far on the basis of the above embodiment. However, the present invention is not limited to this embodiment. The present invention includes other embodiments implemented by applying modifications conceived by those skilled in the art or by combining components of different embodiments as long as these other embodiments do not depart from the scope of the present invention.

The embodiment disclosed thus far only describes an example in all respects and is not intended to limit the scope of the present invention. It is intended that the scope of the present invention not be limited by the described embodiment, but be defined by the claims set forth below. Meanings equivalent to the description of the claims and all modifications are intended for inclusion within the scope of the following claims.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention is useful as a semiconductor device which is bonded to an external substrate according to a flip-chip method or the like, and also useful as a method of manufacturing the semiconductor device.

What is claimed is:

1. A semiconductor device which is bonded to an external substrate, said semiconductor device comprising:
a substrate which is flat; and
a stress generating film which is formed on at least a part of said substrate,
wherein said substrate includes a first surface and a second surface which is opposite to said first surface,
said first surface of said substrate includes a protruding part at each of two end portions,
said substrate includes a semiconductor element,
said stress generating film is formed so as to come into contact with said second surface of said substrate, and
said stress generating film is in a shape which causes a second stress that offsets at least a part of a first stress occurring as a result of bonding between said external substrate and said protruding part.

2. The semiconductor device according to claim 1,
wherein said protruding part includes:
an electrode pad which is electrically connected to said semiconductor element; and
a bump which is electrically connected to said electrode pad.

3. The semiconductor device according to claim 1,
wherein said stress generating film is in a shape of a closed loop; and
said stress generating film is formed along a periphery of said second surface of said substrate.

4. The semiconductor device according to claim 1,
wherein said stress generating film is in a shape of a closed loop; and
said stress generating film is in a shape of an octagon.

5. The semiconductor device according to claim 1,
wherein said stress generating film is in a shape of an ellipse.

6. The semiconductor device according to claim 1,
wherein said stress generating film includes a plurality of closed-loop-shaped flat sub-films which are different in size.

7. The semiconductor device according to claim 1,
wherein a side surface of said substrate is flush with a side surface of said stress generating film.

8. The semiconductor device according to claim 1,
wherein said stress generating film is made of a resin material, in whole or in part.

9. The semiconductor device according to claim 1,
wherein said stress generating film is made of an oxide film or a nitride film, in whole or in part.

10. The semiconductor device according to claim 1,
wherein said semiconductor device is bonded to said external substrate according to a flip-chip method.

11. A method of manufacturing a semiconductor device which includes a flat substrate having a semiconductor element and which is bonded to an external substrate, the flat substrate including a first surface and a second surface which is opposite to the first surface,
said method comprising:
forming a protruding part on the first surface of the flat substrate at each of two end portions;
forming a stress generating film so that the stress generating film comes into contact with the second surface of the flat substrate; and
forming the stress generating film in a shape which causes a second stress that offsets at least a part of a first stress occurring as a result of bonding between the external substrate and the protruding part.

12. The method of manufacturing the semiconductor device according to claim 11, further comprising
grinding the flat substrate to reduce a thickness of the flat substrate to 50 μm to 300 μm, said grinding being performed between said forming of a protruding part and said forming of a stress generating film.

13. The method of manufacturing the semiconductor device according to claim 11,
wherein the semiconductor device is bonded to the external substrate according to a flip-chip method.
